(19) United States
(12) Patent Application Publication
(10) Pub. No.: US 2004/0150417 A1
(43) Pub. Date: Aug. 5, 2004

(54) Integrated circuit with junction temperature sensing diode

(76) Inventor: John James Paulos, Austin, TX (US)

Correspondence Address: HOWISON & ARNOTT, L.L.P, P.O. BOX 741715, DALLAS, TX, 75374-1715, US

(21) Appl. No.: 10/354,582

(22) Filed: Jan. 30, 2003

(51) Int. Cl. G01R 31/02

(52) U.S. Cl. 324/760

(57) ABSTRACT

Integrated circuit with junction temperature sensing diode. An integrated circuit with temperature sensing capabilities is disclosed. The integrated circuit includes a substrate for containing circuitry on the surface thereof. At least one section of the circuitry on the surface of the substrate is operable, during a normal operating mode, to raise the surface temperature of the substrate. A sensing element is disposed within the at least one section for sensing temperature varying parameters that vary as a function of temperature. accessing circuitry then is operable for accessing the sensing element during a test mode for output of the sensed temperature varying parameters by the sensing element

### TECHNICAL FIELD OF THE INVENTION

This invention pertains in general to systems for determining the operating temperature of a die in an integrated circuit package and, more particularly, to the use of a diode sensing device incorporated within the integrated circuit die for sensing temperature.

### BACKGROUND OF THE INVENTION

In systems utilizing integrated circuits, the operating temperature of the system has seen increasing attention due to the fact that a number of these integrated circuits operate at fairly high current levels, thus resulting in high die temperatures in the integrated circuit. Typically, these integrated circuits are singled out and heat sinks associated therewith, such as, for example, a CPU that has a heat sink with mini-fans associated therewith. In addition, there is provided a power supply fan and, to an increasing extent, extra ventilating fans for the case.

As the die temperatures increase, the operating characteristics of the parts of the integrated circuit can be impeded, as well as there being a potential for a decrease in the useful life of the integrated circuit. A problem exists when dealing with fairly dense digital integrated circuits with a relatively high clock speed in that die temperature can be excessively high in certain regions. However, present ventilation/heat sink/cooling techniques may not be sufficient to maintain the die temperature for a particular integrated circuit at a sufficiently low enough temperature. The problem is that the die temperature is difficult to ascertain on these circuits without some complex modeling techniques that not only involve the integrated circuit, but also must consider the mounting PC boards, the enclosure, the surrounding integrated circuits, etc. There are some systems that actually provide for measurement of the package temperature. However, these types of systems have inaccuracies due to the thermal characteristics of the surrounding materials in the package. There are also some on-chip temperature measuring devices such as those associated with band-gap generators, that are used to measure ambient temperature. These systems actually measure the die temperature which is assumed to be substantially equal to the ambient temperature due primarily to the fact that these are very low power applications.

### SUMMARY OF THE INVENTION

The present invention disclosed and claimed herein, in one aspect thereof, comprises an integrated circuit with temperature sensing capabilities. The integrated circuit includes a substrate for containing circuitry on the surface thereof. At least one section of the circuitry on the surface of the substrate is operable, during a normal operating mode, to raise the surface temperature of the substrate. A sensing element is disposed within the at least one section for sensing temperature varying parameters that vary as a function of temperature. Accessing circuitry then is operable for accessing the sensing element during a test mode for output of the sensed temperature varying parameters by the sensing element.

### BRIEF DESCRIPTION OF THE DRAWINGS

For a more complete understanding of the present invention and the advantages thereof, reference is now made to the following description taken in conjunction with the accompanying Drawings in which:

FIG. 1 illustrates a diagrammatic view of an integrated circuit board containing a plurality of integrated circuits in a case;

FIG. 2 illustrates a cross sectional view of an integrated circuit;

FIG. 3 illustrates a top view of the integrated circuit of FIG. 2;

FIG. 4 illustrates a side view of the integrated circuit of FIG. 3 with its temperature profile;

FIG. 5 illustrates a schematic of the current source in the series with the temperature sensing diode;

FIG. 5A illustrates a curve of voltage vs. temperature in ambient atmosphere for the diode of FIG. 5;

FIG. 6 illustrates a perspective view of the diode incorporated in a sensing section;

FIG. 7 illustrates a diagram of the test mode for an embodied temperature sensing diode;

FIGS. 8-10 illustrate alternate embodiments of FIG. 7;

FIG. 11 illustrates a diagrammatic view of the embodied diode within the sense section with a control section illustrated;

FIG. 12 illustrates an alternate embodiment where multiple temperature sensing diodes are provided for;

FIG. 13 illustrates a flow chart for the diode calibration operation; and

FIG. 14 illustrates a flow chart for the measurement operation.

### DETAILED DESCRIPTION OF THE INVENTION

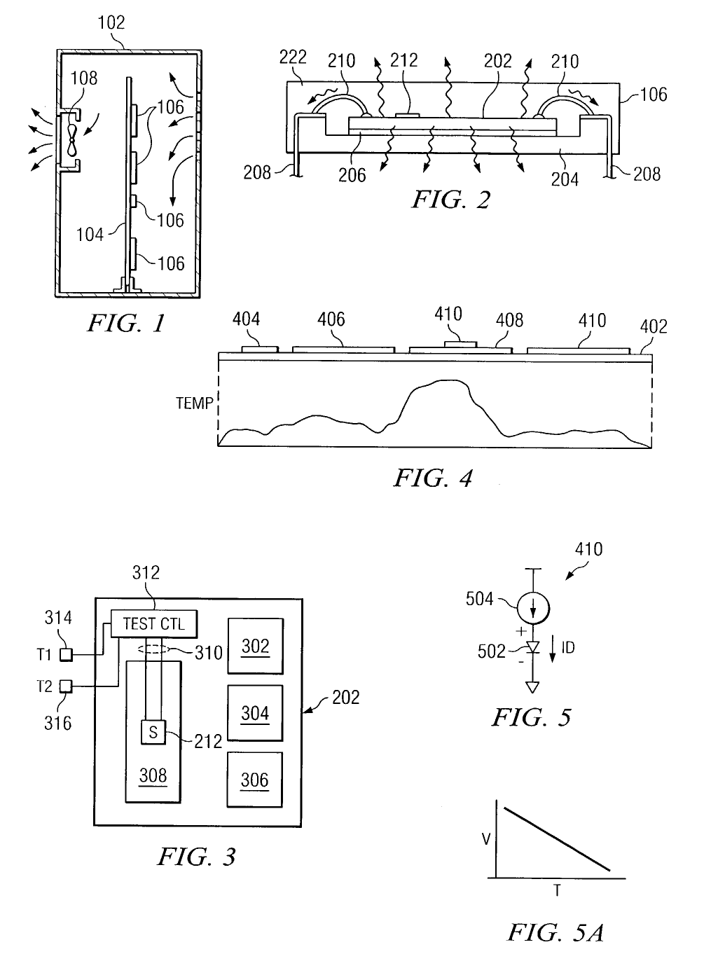

Referring now to FIG. 1, there is illustrated a diagrammatic view of a computer case 102 having contained therein a PC board 104 with integrated circuits 106 disposed thereon. At least one of these integrated circuits 106 has contained therein the sensing device of the present disclosure. The case 102 has associated therewith a cooling fan 108, which cooling fan 108 is operable to draw air through the case 102. This is for the purpose of maintaining a low ambient temperature. It is desirable that the ambient temperature be maintained at such a level that the operating temperature on the die of any of the integrated circuits 106 is maintained below a maximum operating temperature for that die. However, depending upon how the integrated circuit 106 is mounted on the board 104 and the location within the case 102 can be determinative of how well the integrated circuit 106 is cooled. As such, the temperature of the ambient air will not necessarily be a valid representation of the actual die temperature.

Referring now to FIG. 2, there is illustrated a cross sectional view of the integrated circuit 106. The integrated circuit 106 is representative of any type of integrated circuit and typically includes a die 202 that is adhered to some type of substrate 204 associated with the package with a die attach layer 206. This die attach layer 206 can be any type of attachment which is well known in the industry. The package will have a plurality of leads 208 that provide for mounting onto the board 104, these leads shown with a conventional “pin.” However, various other types of attachment techniques can be utilized such as solder balls for “flip-chip” applications. With leads, the pads associated with input/output functions of the integrated circuit on the die 202 will need to be connected to the pins 208. This will utilize bonding wires 210. Disposed on the die 202 and integral with the integrated circuit is a sensing device 212 that is operable to determine the temperature on the surface of the die at a particular location on that die.

The integrated circuit 106 with the die 202 disposed thereon will typically, in some applications, be encapsulated within some type of resin encapsulation 222. Once the package is encapsulated in this instantiation, the thermal transfer characteristics of the materials surrounding the die 202 will greatly affect how heat is removed from the die 202. Current, of course, is input to the device through one of the terminals and the bond wire and then dissipated within the die across the surface thereof. However, in present integrated circuits, there are many circuit “modules” or “sections” that require different levels of power. As such, one section of the die may have a different temperature profile than others due to the concentration of power therein and the thermal resistance in the horizontal direction extending outwards therefrom. This high power portion will, of course, result in the highest localized die temperature. This heat that is generated on the die at any particular location thereon, is pulled away from the die 202 through either the package at die attach layer 206, through the bonding wires or through the encapsulated materials from the top of the die 202. Since packages can take many forms, it can be appreciated that thermal transfer characteristics between the surface of the die 202 and the exterior of the package will vary greatly.

Referring now to FIG. 3, there is illustrated a top view of the integrated circuit die 202 with a plurality of integrated circuit sections defined thereon. These are for exemplary purposes only, and it should be understood that any type of integrated circuit can be utilized. The reason to provide the different sections is that some sections will have significantly higher power consumption than others and, therefore, localized die temperature in that section will tend to be higher, such applications being those associated with circuitry having digital and analog sections on the same integrated circuit. One such application is a high speed Ethernet chip. One reason for the localized temperature of one section being higher than others is due to the fact that, as the size of the conventional die increases and the circuit density increases with high clocking rates, the lateral dissipation of heat is insufficient to adequately distribute heat across the integrated circuit which will result in localized temperature increases. There are illustrated four integrated circuit sections 302, 304, 306 and 308 on the die 202, each have a different functionality associated therewith. For example, some of the sections may be associated primarily with analog functions, some with I/O functions and some with low power digital functions. However, the section 308, for this example, is one that is associated with relatively high power circuitry that requires substantially more current to operate than the other sections and is also associated with fairly dense circuitry. As such, the surface temperature will be fairly high from a localized standpoint, as compared to the other sections. Of course, there could be other sections will relatively high power associated therewith also.

The sensing device 212 is disposed within the circuitry 308 at a particular point. This point can be determined from actual measurements. However, it will in this embodiment be disposed within the substantial center at the most dense portion of the circuitry where the temperature would be expected to be highest. This sensing circuit 212 is connected through leads 310 to a test control circuit 312 which interfaces with two test control pins 314 and 316. During tests, as will be described in more detail hereinbelow, this sensing device 212 is calibrated with the power consumption in the section 308 reduced to a minimal and insignificant level. In this manner, the output of the sensing device 212 can be measured as a function of the ambient temperature to generate a plot of voltage output vs. temperature. Thereafter, when the section 308 is fully powered and operational, the voltage output of the sensing device 212 can be measured in a test mode to provide a voltage output that is compared to the plot to determine the temperature of the die of the section 308 as opposed to the temperature of the package or the ambient temperature.

Referring now to FIG. 4, there is illustrated a side view of an integrated circuit die 402 that illustrates on the surface thereof four integrated circuit sections 404, 406, 408 and 410. A temperature profile is illustrated across the surface of the die 402 when it is operating. This profile illustrates that the section 408 has a substantially higher temperature than the other sections 404, 406 and 410. As such, the temperature sensing device 410 is disposed in a select portion of the section 408. By examining the output of this temperature sensing device 410, the maximum operating temperature of the die can be determined, it being recognized that it is assumed that the highest temperature on the die in any localized region will be in substantially the region that the sensing device 410 is disposed.

Referring now to FIG. 5, there is illustrated a schematic diagram of the sensing device 410, which is substantially the same sensing device 212. The sensing device 410 is a diode 502 which is oriented such that it will have a constant current applied thereto with a current source 504 that is disposed between the positive supply V_{DD} and the anode of diode 502, the cathode of diode 502 connected to ground. This will result in a diode current I_{D} flowing through the diode 502. The diode has the following relationship:

$$\frac{KT}{q} ln ( \frac{I}{{I}_{o}} )$$

where K=Boltzmann's constant

I_{O}=a current constant

The temperature coefficient for the diode 502 is approximately −2.5 mV/C. As such, measuring the voltage across the diode for a 10° C. difference in temperature will only require being able to resolve a 25 mV voltage difference. In FIG. 5A, it can be seen that measurement of the diode 502 in an ambient atmosphere would result in a curve of voltage vs. temperature that decreases as temperature increases. As will be described hereinbelow, the diode 502 is calibrated after the design has been implemented in a test mode. In this test mode, the primary power consuming circuitry is powered down and then the voltage across the PN junction of diode 502 measured as a function of temperature in a test oven. This will basically comprise the combination of the current source 504 and diode 502. When the device is powered up at a later time, it is only necessary to measure the voltage and then correlate this voltage with the appropriate temperature which is known from the calibration curve.

The current source 504 can be realized with a number of different configurations which, in this embodiment, is one that is fabricated on the semiconductor substrate with the other circuitry. One such embodiment utilizes a temperature independent voltage source to drive a temperature independent resistor to provide a temperature independent current. This can then be mirrored to provide the current to the diode 504. The temperature independent voltage source can be realized with an on-chip band gap generator and the temperature independent resistor can be an external resistor that is disposed at the ambient temperature.

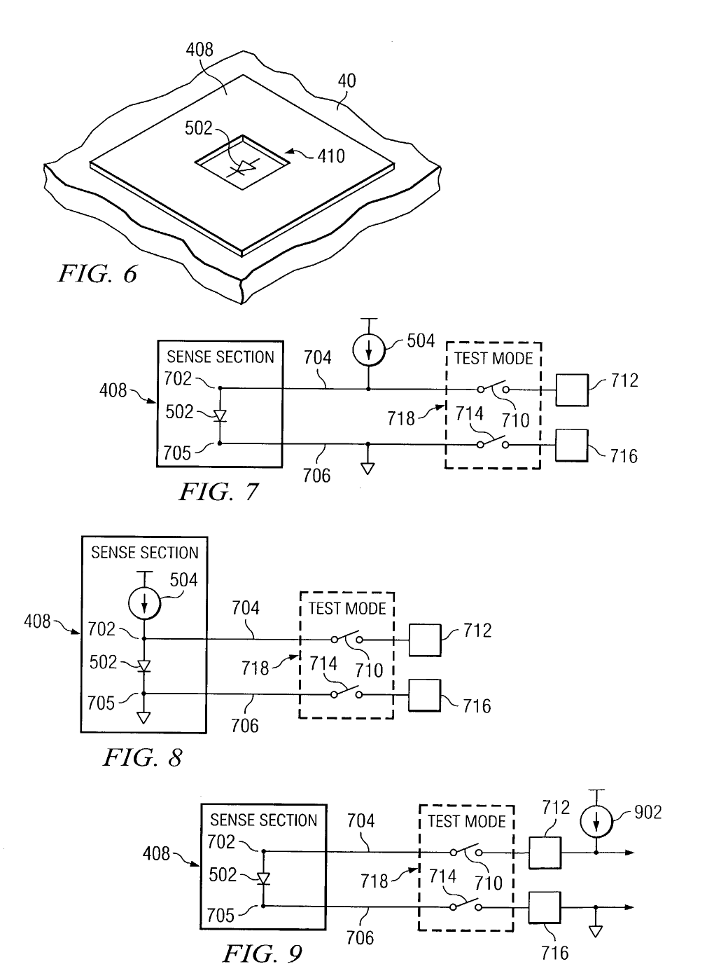

Referring now to FIG. 6, there is illustrated a perspective view of the integrated circuit die 402 and the section 408 in which the sensing device 410 is disposed. The sensing device 410, as described hereinabove with respect to FIG. 5, comprises the diode 502. The diode 502 in the standard cell is inserted into the integrated circuit section 408 and at a predetermined location. In the present embodiment, the section 408 is comprised of a digital section in a circuit such as an Ethernet integrated circuit. These Ethernet integrated circuits operate in the 10 Megabit mode, the 100 Megabit mode and the 1 Gigabit mode. In the 1 Gigabit mode, the power consumption is the highest, due to the processing required in the digital section and the high clocking rate. It is at this level that the surface temperatures are of most concern. Therefore, there will exist in such a circuit a digital section or digital “route” which will generate the most heat due to power consumption. The diode 502 is placed in substantially the center of this section and leads run out from the diode 502 external to the section 408 to provide access to the diode 502 to allow measurement of the junction thereof.

Referring now to FIGS. 7-10, there are illustrated diagrammatic views of various embodiments of how the test mode is configured. With specific reference to FIG. 7, the integrated circuit section 408 is referred to as a “sense section.” The diode 502 has an anode 702 that is connected through a line 704 to the current source 504. The cathode of the diode 502 is connected to a node 705 and to a line 706 that extends out of the sense section 408 and is connected to ground. In the embodiment of FIG. 7, the ground connection is illustrated as occurring outside of the sense section 408. However, it should be understood that the diode 502 could be connected such that the node 705 is connected to ground within the sense section or at any place on the circuit where an adequate ground connection can be facilitated. It is only important that the node 705 be connected to a run that can be accessed for measuring the voltage across the diode 502.

Line 704 is connected to one side of a switch 710, the other side thereof connected to an external terminal 712 in the integrated circuit. The line 706 connected to node 705 on the cathode of the diode 502 is connected to one side of a switch 714, the other side thereof connected to an external terminal 716 on the integrated circuit. There is illustrated a box 718 around the switches 710 and 714, this illustrated as a test mode box. This receives a test mode signal which is operable to connect the nodes 702 and 705 to the terminals 712 and 716 such that the voltage across the diode 502 can be measured in that mode.

Referring now to FIG. 8, there is illustrated an alternate embodiment wherein the current source 504 is contained within the sense section 408 and the ground connection is also contained within the sense section 408. As noted hereinabove, it should be understood that the current source 504 can be contained within the sense section 408 where it can be external thereto. Typically, it would be outside of this sense section due to the temperature variation associated with the higher temperature in the sense section 408.

Referring now to FIG. 9, there is illustrated an alternate embodiment of the embodiment of FIG. 7. In this embodiment, an external current source 902 is utilized that is connected to the external terminal 712 outside of the integrated circuit and a ground is connected to terminal 716 such that current is provided external to the integrated circuit, run through the pass through diode 502 and brought back out through terminal 716. Of course, the diode 502 would be calibrated in this method also.

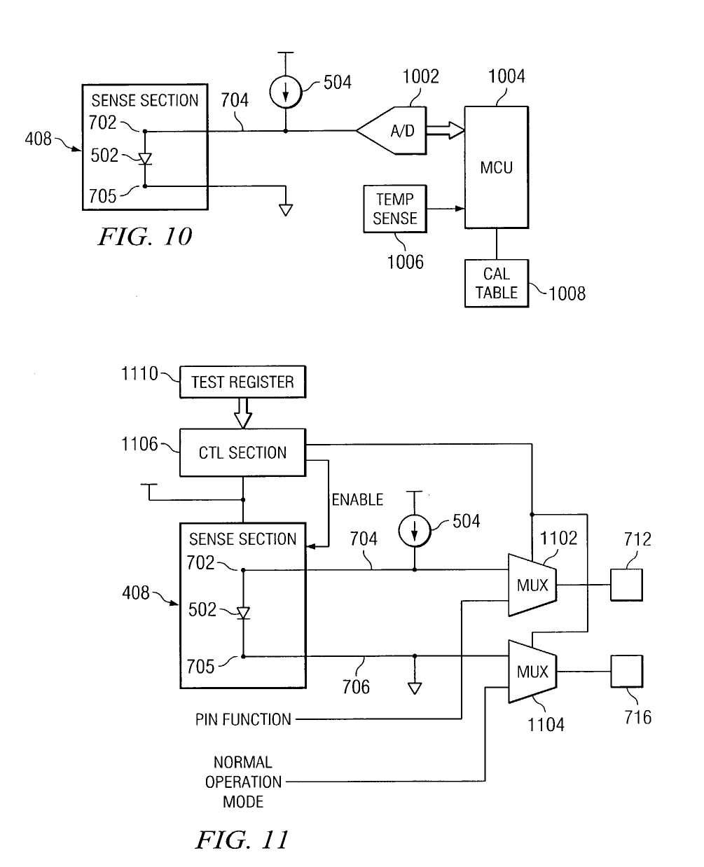

Referring now to FIG. 10, there is illustrated an alternate embodiment to the embodiment of FIG. 7. In the embodiment of FIG. 10, the voltage across the nodes 702 and 705 of the diode 702 is measured by inputting the voltage on line 704 to the input of an analog-to-digital converter (A/D) 1002. This allows the conversion of the analog voltage to a digital voltage for processing by a onboard microcontroller unit (MCU) 1004. The MCU 1004 provides an internal voltage measurement and the calibration information that is derived during a calibration mode, wherein the sense section 408 is disabled and the voltage across the diode 502 measured. This is compared to a known temperature which is derived by the MCU 1004 utilizing an on-chip temperature sensor 1006. This temperature sensor 1006 can be realized with circuitry such as a band gap reference generator. This band gap reference generator, when operating in a low power mode and a corresponding low temperature mode, i.e., wherein high power sections of the circuitry are disabled, can determine the temperature of the die which is substantially at the ambient temperature during operation. Therefore, the MCU 1004 with use of the temperature sensor 1006 will have information as to the ambient temperature. This is utilized to create a calibration table for storage in a calibration storage area 1008. This is facilitated by placing the integrated circuit in an oven and cycling the temperature. As the temperature cycles, the MCU 1004 can take periodic measurements at predefined temperature increments. Since the high power section is disabled, the temperature measured is that of the ambient air. During normal operation with the high powered section powered and dissipating heat, the MCU 1004 can utilize this calibration information and the information from the A/D converter 1002 to determine the temperature of the chip proximate the high powered section. This can be used for various purposes.

Referring now to FIG. 11, there is illustrated a more detailed diagram of the overall control of the test mode. The line 704 is input to one input of a multiplexer 1102, the other input thereof connected to an internal pin function, and the output of multiplexer 1102 connected to terminal 716. The multiplexer 1102 is operable to, in normal operation, utilize the terminal 712 for a predefined function. This predefined function is utilized except in the measurement or test mode wherein the line 704 is selected. Similarly, line 706 is input to one input of a multiplexer 1104, the other input thereof connected to another internal pin function which is utilized in the normal operating mode. Multiplexers 1102 and 1104 are controlled by a control block 1106 which control section 1106 is operable to control the multiplexers 1102 when operating in the test mode. The control section has two modes of operation. The first mode is on where the system is calibrated and the second is one where it is merely tested in normal operation. In a calibration mode, the multiplexers 1102 and 1104 are set to select lines 704 and 706 to measure the voltage across the diode 502. In the calibration mode, the control section 1106 is operable to disable the operation of the sense section 408. This disabling operation can occur in a number of ways. Some digital circuitry can be powered down by forcing a predetermined condition thereto or the clock signal that runs the section 408 can be disabled. A power switch can also be provided for disconnecting power from the particular sense section 408. Any type of system that will result in powering down the sense section 408 can be utilized. The control section 1106 is typically disposed outside of the sense section 408. Therefore, a user need only write information to a test register 1110, which test register is operable to set the control section to the appropriate mode. Although not shown, other circuitry on the integrated circuit will allow reading and writing of the test register.

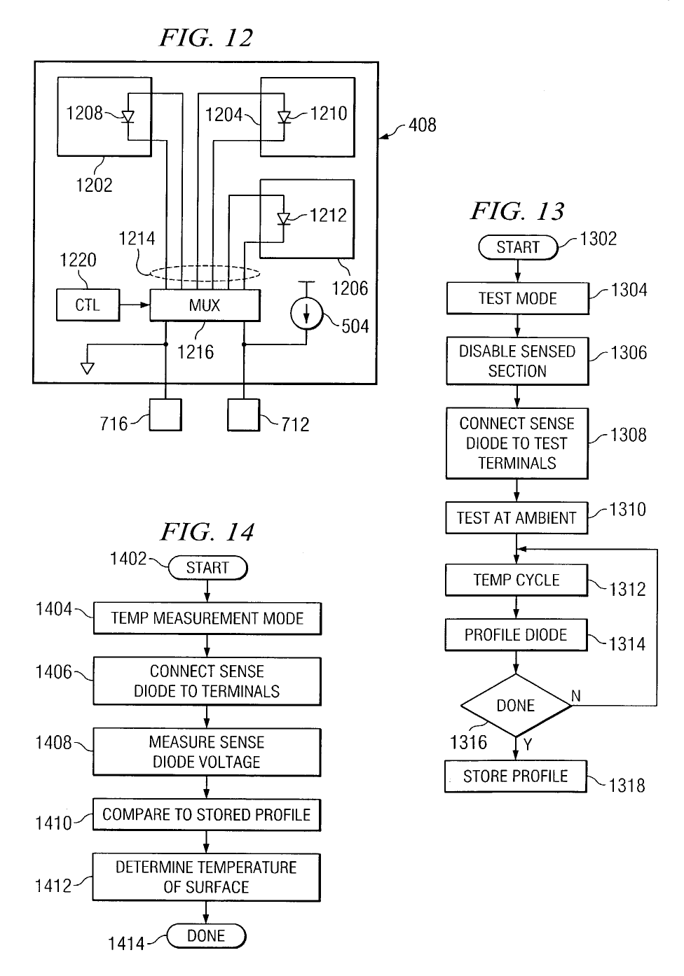

Referring now to FIG. 12, there is illustrated a diagrammatic view wherein the integrated circuit die has three sections 1202, 1204 and 1206 disposed thereon. All of these sections can have a separate sense diode 1208, 1210 and 1212, respectively, disposed at predetermined locations therein. Each of the diodes 1208-1212 have associated therewith current sources (not shown) with voltage lines 1214 disposed thereacross and input to a multiplexer 1216. The multiplexer 1216 is operable to select between one of three sets of the lines 1214 to measure the voltage across the associated diodes 1208-1212. This multiplexer 1216 is controlled by a control block 1220. The multiplexer 1216 is operable to provide outputs to the external terminals 712 and 716, as described hereinabove. In general, the embodiment of FIG. 12 allows for more than one sense node to be disposed on an integrated circuit for the purpose of taking different readings at different locations.

In the embodiment of FIG. 12, the current source is connected to the output of the multiplexer 1216 associated with the terminal 712 and a ground connection is associated with the output of the multiplexer 1216 that is connected to the terminal 716. As such, whenever the multiplexer selects one of the sets of lines 1214 associated with the diodes 1208, 1210 or 1212, current will be passed therethrough. This therefore allows a user to create a thermal profile of a chip. In some situations, it is desirable to have knowledge of localized heating at different areas on the chip. These can be one or two areas or any number of areas.

Referring now to FIG. 13, there is illustrated a flowchart depicting the operation of profiling the diode. During manufacturing of a new part, the actual thermal profile of the part is difficult to model. However, if a thermal profile could be taken of the chip, this profile would be a fairly repeatable profile over all production parts. The problem is that this temperature profile is a relative temperature profile that is relative to the base temperature of the substrate, the type of heat sink that the package is disposed on, etc. Thus, having an on-chip temperature sensor will provide information as to the localized temperature.

The program is initiated at a block 1302 and then proceeds to a block 1304 wherein the test mode is set in a register on-chip. Once this mode of operation is entered, the section to be sensed is disabled, as indicated by a function block 1306 such that the sensed section operates at a relatively low power level and the temperature profile of the chip is fairly flat. Of course, although the sense section is the section of interest, there may be other sections that also generate heat. These sections will also be disabled if necessary to ensure that there is substantially no heat generated by the part that cannot be extracted therefrom by the chip merely being mounted in a test socket, i.e., the temperature is fairly flat over the entire chip area and it is at substantially ambient temperature. The program then flows to a function block 1308 wherein the sense diode is connected to the test terminal. However, it should be understood that dedicated test terminals could be provided that would always be connected across the sense diode. The program then flows to a function block 1310 wherein a test is performed at ambient, i.e., room temperature. The program then flows to a function block 1312, which consists of placing the test integrated circuit into an oven and then cycling the temperature thereof to measure the voltage across the sense diode at predefined increments of temperature. The program then flows to a function block 1314 wherein the diode is profiled over this temperature cycle and then to a decision block 1316 to determine if the profiling is done, i.e., if it has been cycled through all the desired temperatures. If not, the program proceeds along the “N” path back to the input of function block 1312. When complete, the program will flow along the “Y” path to a function block 1318 to store the profile.

Referring now to FIG. 14, there is illustrated a flowchart depicting a measurement mode. This is initiated at a block 1402 and then proceeds to a function block 1404 to set the system in the temperature measurement mode. In this mode, the chip operates as normal and the particular sense section is not disabled. As such, the temperature sensing diode will be disposed at the localized temperature of the sense section. The program will proceed to a function block 1406 to connect the sense diode to the test terminals, it being noted again that the anode and cathode of the sense diode could be connected to the terminal at all times. The program then flows to a function block 1408 to measure the sense diode voltage and then to a function block 1410 to compare the measured voltage to the stored profile. A determination can then be made as to the temperature of the surface proximate the sense diode, as indicated by function block 1412. The program then proceeds to a Done block 1414.

Although the preferred embodiment has been described in detail, it should be understood that various changes, substitutions and alterations can be made therein without departing from the spirit and scope of the invention as defined by the appended claims.

What is claimed is:

1. An integrated circuit with temperature sensing capabilities, comprising:
a substrate for containing circuitry on the surface thereof;
at least one section of the circuitry on the surface of said substrate operable, during a normal operating mode, to raise the surface temperature of the substrate;
a sensing element disposed within said at least one section for sensing temperature varying parameters that vary as a function of temperature; and
accessing circuitry for accessing said sensing element during a measurement mode for output of the sensed temperature varying parameters sensed by said sensing element.

2. The integrated circuit of claim 1 wherein said at least one section of the circuitry will only raise the surface temperature in the area local to said at least one section, and other sections on the surface of said integrated circuit have a lower temperature.

3. The integrated circuit of claim 2 wherein said at least one section comprises the highest power consuming section on the surface of said substrate.

4. The integrated circuit of claim 1 wherein said sensing element comprises a diode disposed at a predetermined location within said at least one section of the circuitry, said temperature varying parameters comprising the temperature varying characteristics of the associated diode PN junction.

5. The integrated circuit of claim 4 and further comprising a driving circuit for driving current through said diode to develop a voltage across the diode PN junction.

6. The integrated circuit of claim 5 wherein said driving circuit comprises a current source.

7. The integrated circuit of claim 6 wherein said current driver is disposed on the surface of said substrate and is part of said circuitry.

8. The integrated circuit of claim 1 wherein said substrate includes at least a second section of circuitry different than said at least one section of the circuitry.

9. The integrated of claim 8 and further comprising control circuitry for disabling substantially all operation of said at least one section of the circuitry during a test mode prior to said accessing circuitry accessing said sensing element during said measurement mode.

10. The integrated circuit of claim 1, wherein the integrated circuit has associated therewith a plurality of interface pins for interfacing the circuitry external to the integrated circuit, and wherein said accessing circuitry is operable to output said sensed temperature varying parameters utilizing at least one of said interface pins.

11. The integrated circuit of claim 10, and further comprising a multiplexer for selectively interfacing either said sensed temperature varying parameters during said measurement mode of operation, or another output from said circuitry utilizing at least said one of said interface pins during normal operation.

12. A method for testing localized temperature on the surface of an integrated circuit having a substrate for containing circuitry on the surface thereof, comprising the steps of:
disposing a sensing element within at least one section of the circuitry on the surface of the substrate operable which at least one section of the circuitry, during a normal operating mode, will raise the surface temperature of the substrate, which sensing element on the at least one section is operable for sensing temperature varying parameters of the at least one section of the circuitry that vary as a function of temperature; and
accessing the sensing element during a measurement mode during the normal operating mode for output of the sensed temperature varying parameters by the sensing element.

13. The method of claim 12 wherein the at least one section of the circuitry will only raise the surface temperature in the area local to the at least one section and other sections on the surface of the integrated circuit have a lower temperature.

14. The method of claim 13 wherein the at least one section comprises the highest power consuming section on the surface of the substrate.

15. The method of claim 12 wherein the step of disposing a sensing element comprises disposing a diode at a predetermined location within the at least one section of circuitry.

16. The method of claim 15 and further comprising driving current through the diode to develop a voltage across the diode junction.

17. The method of claim 16 wherein the step of driving comprises driving current through the diode to develop a voltage across the diode junction with a current driver.

18. The method of claim 17 wherein the current driver is disposed on the surface of the substrate and is part of the circuitry.

19. The method of claim 12 wherein the substrate includes at least a second section of circuitry different tan the at least one section of circuitry.

20. The integrated of claim 19 and further comprising the step of disabling substantially all operation of the at least one section of circuitry during a test mode prior the step of accessing in the measurement mode.

21. The method of claim 12, and further comprising the step of comparing the sensed temperature varying parameters with a relational table containing the relation between the temperature varying parameters and the sensing element to determine the localized temperature around the sensing element.

22. The method of claim 12, and further comprising the step of generating a relational table containing the relation between the temperature varying parameters and the sensing element.

23. The method of claim 22, wherein the step of generating the relational table comprises the steps of:
disabling the operation of substantially all of the circuitry on the substrate;
cycling the substrate through temperature;
performing the step of accessing at a plurality of temperature points; and
creating a profile of the sensed parameters of the sensing elements over the temperature points in a table.

24. The method of claim 12, wherein the integrated circuit has associated therewith a plurality of interface pins for interfacing the circuitry external to the integrated circuit, and wherein the step of accessing is operable to output the sensed temperature varying parameters utilizing at least one of the interface pins.

25. The integrated circuit of claim 24, and further comprising the step of selectively interfacing either said sensed temperature varying parameters during the measurement mode of operation, or another output from the circuitry utilizing at least the one of the interface pins during normal operation.

26. A method for determining the highest surface temperature on a substrate mounted in a packaged integrated circuit, the substrate having disposed thereon powered circuitry that dissipates heat during normal operation thereof, comprising the steps of:
measuring temperature varying parameters in a localized portion of the substrate proximate to a region of the circuitry that has been determined to have the highest operating temperature during normal operation thereof; and
comparing the measured parameters with a correlation values that correlate the measured parameters to actual temperature values, such that the absolute temperature of the localized portion can be determined.

27. The method of claim 26, wherein the step of measuring the temperature varying parameters comprises measuring temperature varying parameters of an active semiconductor device fabricated on the substrate as an integral part of the circuitry and disposed at the localized portion of the substrate.

28. The method of claim 27, wherein the active device comprises a semiconductor diode with a PN junction, the parameters thereof when operating under power comprising the temperature varying parameters.

29. The method of claim 27, wherein the step of measuring includes the step of powering the active device with a power circuit that has a known temperature profile wherein the temperature varying parameters of the active device are a function of the active device operating under power.

30. The method of claim 29, wherein the step of powering the active device comprises the step of providing power from a source external to the integrated circuit.

31. The method of claim 28, wherein the step of providing power from a source external to the integrated circuit comprises providing power from a source external to the integrated circuit through interface pins on the integrated circuit.

32. The method of claim 28, wherein the step of powering the active device comprises the step of providing power from a source internal to the integrated circuit to the active device, which source is part of the circuitry on the substrate.
